(19) United States
(12) Patent Application Publication
(10) Pub. No.: US 2014/0027757 A1
(43) Pub. Date: Jan. 30, 2014

(54) NOVEL SPIRO COMPOUND AND ORGANIC LIGHT-EMITTING DEVICE HAVING THE SAME

(71) Applicants: Naoki Yamada, Inagi-shi (JP); Taiki Watanabe, Akishima-shi (JP); Kengo Kishino, Tokyo (JP); Jun Kamatani, Tokyo (JP)

(72) Inventors: Naoki Yamada, Inagi-shi (JP); Taiki Watanabe, Akishima-shi (JP); Kengo Kishino, Tokyo (JP); Jun Kamatani, Tokyo (JP)

(73) Assignee: CANON KABUSHIKI KAISHA, Tokyo (JP)

(21) Appl. No.: 14/111,527

(22) PCT Filed: Apr. 5, 2012
(86) PCT No.: PCT/JP2012/059951

§ 371 Date: Oct. 11, 2013

(30) Foreign Application Priority Data
Apr. 14, 2011 (JP) 2011-090412
Jan. 26, 2012 (JP) 2012-014365

(51) Int. Cl. H01L 51/00

(52) U.S. Cl. CPC H01L 51/0056; H01L 51/0074; H01L 51/0073
USPC 257/40; 549/41; 549/330; 585/27

(57) ABSTRACT

The present invention provides a novel stable organic compound and also provides an organic light-emitting device having a high luminous efficiency and a low driving voltage. The present invention relates to a spiro compound represented by the following Formula [1]:

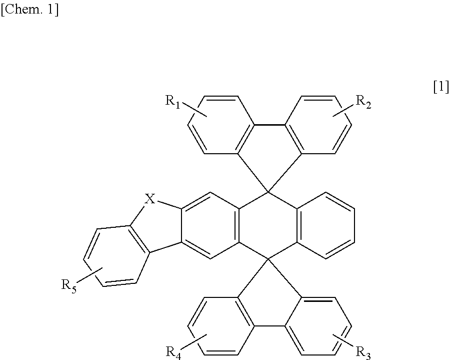

wherein, R₁ to R₅ are each independently selected from hydrogen atoms and alkyl groups having 1 to 4 carbon atoms and may be the same or different; and X is any of a sulfur atom, an oxygen atom, and a carbon atom, and when X is a carbon atom, the carbon atom may have one or two alkyl groups having 1 to 4 carbon atoms, and when the carbon atom has two alkyl groups having 1 to 4 carbon atoms, the two alkyl groups may be the same or different.

### TECHNICAL FIELD

The present invention relates to relates to a novel spiro compound and an organic light-emitting device including the spiro compound.

### BACKGROUND ART

An organic light-emitting device includes a pair of electrodes and an organic compound layer disposed therebetween. A light-emitting organic compound in the light-emitting layer generates excitons by injection of electrons and holes through the pair of electrodes, and light is emitted when the excitons return to their ground state.

Non-Patent Literature 1 describes compound A-1 having a structure shown below and a method of synthesizing the compound.

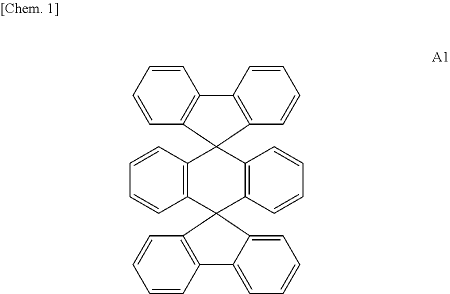 [SMILES: c1ccc2c(c1)-c1ccccc1C21c2ccccc2C2(c3ccccc3-c3ccccc32)c2ccccc21]

Patent Literature 1 describes compounds A-2 and A-3, which are each compound A-1 substituted with an aryl group, as materials for organic light-emitting devices.

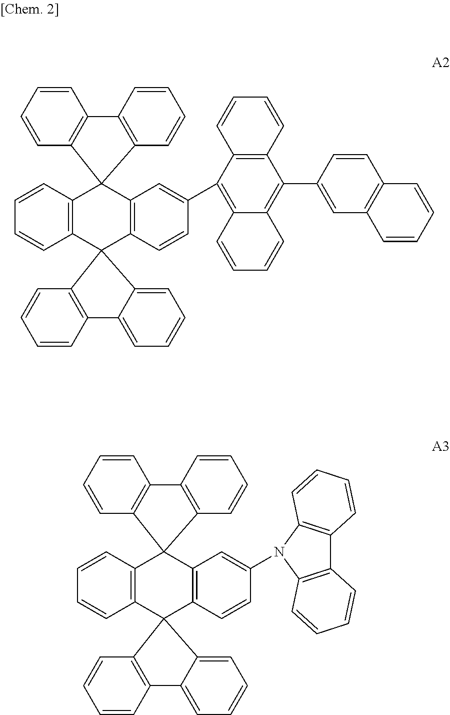

### CITATION LIST

### Patent Literature

PTL 1 International Publication No. WO 02/088274

### Non Patent Literature

NPL 1 Journal of American Chemical Society, Vol. 52, 1930, p. 2881

### SUMMARY OF INVENTION

The present invention provides a novel spiro compound that has a high lowest excited triplet level (T1) and can form a stable amorphous film having high chemical stability and low crystallinity. In addition, the present invention provides an organic light-emitting device having the spiro compound and, thereby, having a high luminous efficiency and a low driving voltage.

The present invention provides a spiro compound represented by the following Formula [1]:

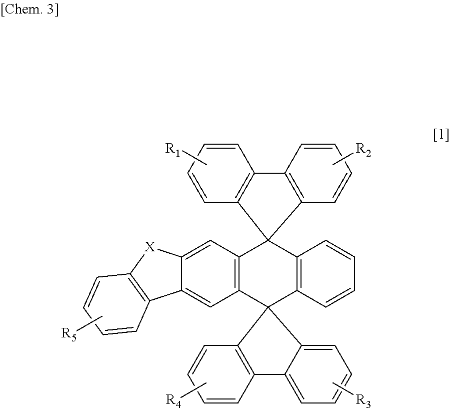

In Formula [1], R₁ to R₅ are each independently selected from hydrogen atoms and alkyl groups having 1 to 4 carbon atoms and may be the same or different; and X is any of a sulfur atom, an oxygen atom, and a carbon atom. When X is a carbon atom, the carbon atom may have one or two alkyl groups having 1 to 4 carbon atoms, and when the carbon atom has two alkyl groups having 1 to 4 carbon atoms, the two alkyl groups may be the same or different.

### BRIEF DESCRIPTION OF DRAWINGS

FIG. 1 is a schematic cross-sectional view illustrating organic light-emitting devices and switching devices connected to the organic light-emitting devices.

### DESCRIPTION OF EMBODIMENT

The present invention provides a spiro compound represented by the following Formula [1]:

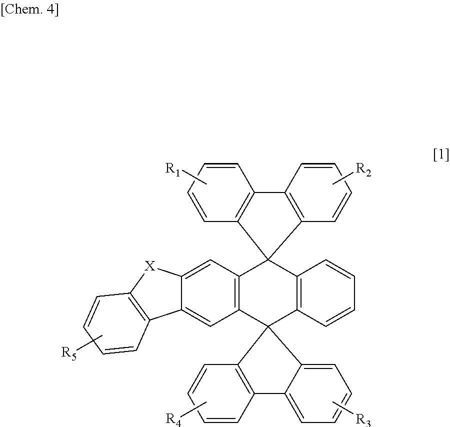

In Formula [1], R₁ to R₅ are each independently selected from hydrogen atoms and alkyl groups having 1 to 4 carbon atoms and may be the same or different; and X is any of a sulfur atom, an oxygen atom, and a carbon atom.

Specific examples of the alkyl group having 1 to 4 carbon atoms represented by R₁ to R₅ include methyl groups, ethyl groups, n-propyl groups, iso-propyl groups, n-butyl groups, iso-butyl groups, sec-butyl groups, and tert-butyl groups.

When X is a carbon atom, the carbon atom may be substituted with one or two alkyl groups having 1 to 4 carbon atoms.

Examples of the alkyl group having 1 to 4 carbon atoms that substitutes the carbon atom represented by X include methyl groups, ethyl groups, n-propyl groups, iso-propyl groups, n-butyl groups, iso-butyl groups, sec-butyl groups, and tert-butyl groups. When X is a carbon atom substituted with two alkyl groups having 1 to 4 carbon atoms, the two alkyl groups may be the same or different. In particular, the two alkyl groups can be the same and can be methyl groups, ethyl groups, or propyl groups.

A condensed polycyclic compound according to this embodiment, spiro compound B-1, is different from the above-mentioned compound A-1 in the following two properties of the spiro compound B-1:

1. forming a stable amorphous film; and
2. having a low ionization potential (IP).

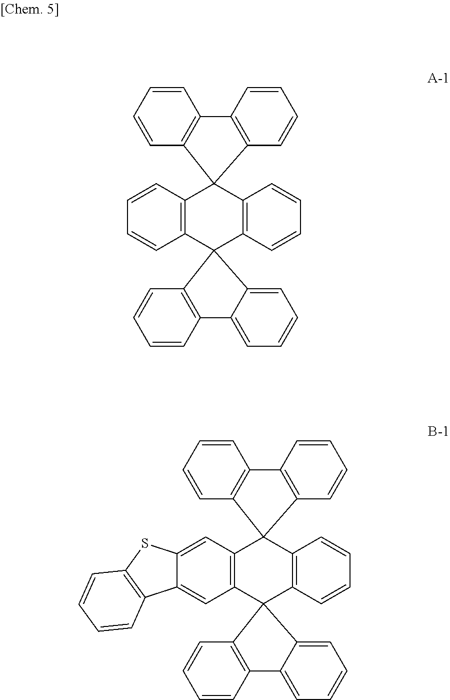

### Description Regarding the Property 1

Compound A-1 has high molecular symmetry due to C2 symmetry and has a low molecular weight, and thereby has a structure that is easily crystallized. On the other hand, spiro compound B-1 has an asymmetry structure and a high molecular weight, and thereby has a structure that is hardly crystallized.

The spiro compound having a structure represented by Formula [1] according to aspects of the present invention forms a stable amorphous film that is hardly crystallized, by, for example, vacuum deposition or spin coating.

### Description Regarding the Property 2

In the spiro compound having a structure represented by Formula [1] according to aspects of the present invention, X is selected from a sulfur atom, an oxygen atom, and a carbon atom optionally substituted with an alkyl group. Since these atoms are electron donative, the ionization potential of spiro compound B-1 is lower than that of compound A-1.

In the case of using the spiro compound represented by Formula [1] as a light-emitting host material in an organic light-emitting device at least having a light-emitting layer and a hole-transporting layer disposed adjacent to the light-emitting layer, the driving voltage of the device can be low. This is because that the spiro compound has a low ionization potential (HOMO level is near the vacuum level) to allow holes to be easily injected from the hole-transporting layer. In this case, the host material refers to the main component of the light-emitting layer. The accessory component is a light-emitting dopant (guest material). The light-emitting dopant emits light, and the host material supplies excitons, electrons, or holes to this light-emitting dopant. In such a case, the HOMO level of the hole-transporting layer is shallower (near the vacuum level) than that of the host material.

Spiro compound B-1 according to aspects of the present invention is different from the above-mentioned compounds A-2 and A-3 in the following properties.

Compounds A-2 and A-3 each have a freely rotating substituent binding to basic skeleton A-1. The freely rotating substituent is anthracene in compound A-2 and carbazole in compound A-3.

On the other hand, the spiro compound represented by Formula [1] according to the present invention does not have a freely rotating aryl group that binds to the skeleton structure. The present inventors consequently believe that the bond by means of thermal energy is hardly cleaved compared to the freely rotating bond.

When all of R₁ to R₅ are hydrogen atoms and X is a sulfur atom, the spiro compound represented by Formula [1] according to the present invention has a very high T1 (lowest excited triplet level), 2.86 eV, in a dilute solution. For example, in compound A-2 which is basic skeleton A-1 having a substituent of a condensed polycyclic compound such as anthracene, the substituent has a low T1. This makes the T1 of the compound A-2 low. In contrast to this, in the spiro compound represented by Formula [1], no aryl group binds to the mother skeleton, and thereby the T1 is high.

Incidentally, the T1 is determined as the first emission peak by cooling a toluene solution (1×10⁻⁴ mol/L) to 77K and measuring the spectrum of the phosphorescence-emitting component at an excitation wavelength of 350 nm. The measurement is performed with a spectrometer U-3010 manufactured by Hitachi, Ltd.

Thus, in the case of using a spiro compound represented by Formula [1] as the host material of an organic light-emitting device, since the spiro compound has a low ionization potential, holes can be easily injected from the organic compound layer such as hole-transporting layer adjacent to the light-emitting layer, and the driving voltage of the device can be low. In addition, the T1 in a dilute solution is 2.86 eV. This energy level is approximately the same as the level for emitting phosphorescence by a blue phosphorescence-emitting dopant. In the case of using the spiro compound as the host material for a blue phosphorescence-emitting device, energy efficiently moves from the host material to the guest material, and as a result, a high efficient blue phosphorescence-emitting device can be provided. Furthermore, the same can be said for devices that emit phosphorescence having a longer wavelength than the blue region, i.e., green or red phosphorescence-emitting devices.

Throughout the specification, the host material refers to the compound having the highest weight ratio among the compounds forming a light-emitting layer. The guest material refers to the compound having a lower weight ratio than the host material and mainly emitting light among the compounds forming a light-emitting layer. The blue emission refers to an energy region of 2.85 to 2.48 eV, i.e., an emission region having a peak top of an emission spectrum waveform in the range of 435 to 500 nm.

In the case of using the spiro compound represented by Formula [1] according to the present invention as the light-emitting layer of an organic light-emitting device, the film of the spin compound formed by vacuum deposition or spin coating is hardly crystallized and is therefore a stable amorphous film. As a result, the device can have a long lifetime.

Specific examples of the spiro compound represented by Formula [1] according to aspects of the present invention are shown below, but the present invention is not limited thereto.

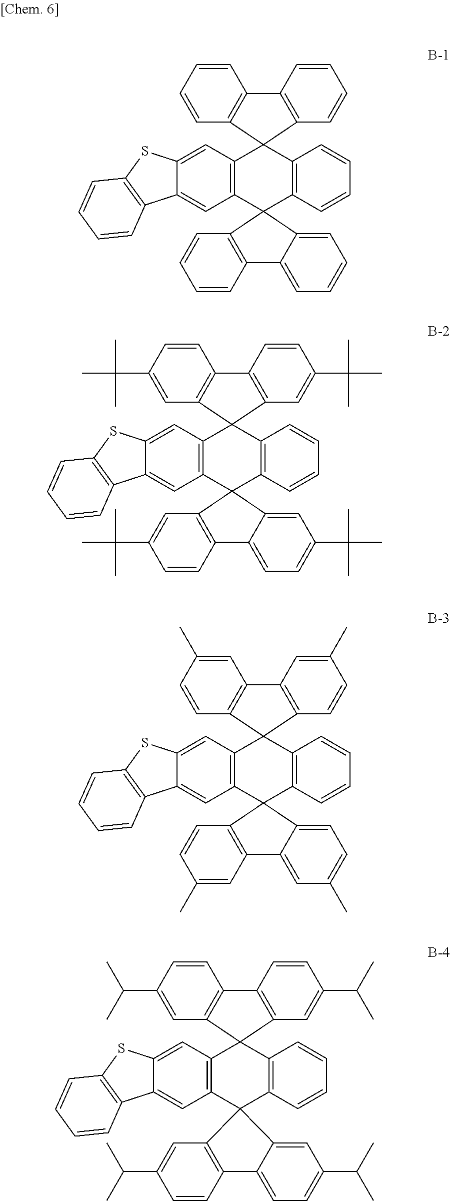 [SMILES: c1ccc2c(c1)-c1ccccc1C21c2ccccc2C2(c3ccccc3-c3ccccc32)c2cc3c(cc21)sc1ccccc13 ; CC(C)(C)c1ccc2c(c1)C1(c3cc(C(C)(C)C)ccc3-2)c2ccccc2C2(c3cc(C(C)(C)C)ccc3-c3ccc(C(C)(C)C)cc32)c2cc3c(cc21)sc1ccccc13 ; Cc1ccc2c(c1)-c1cc(C)ccc1C21c2ccccc2C2(c3ccc(C)cc3-c3cc(C)ccc32)c2cc3c(cc21)sc1ccccc13 ; CC(C)c1ccc2c(c1)C1(c3cc(C(C)C)ccc3-2)c2ccccc2C2(c3cc(C(C)C)ccc3-c3ccc(C(C)C)cc32)c2cc3c(cc21)sc1ccccc13]

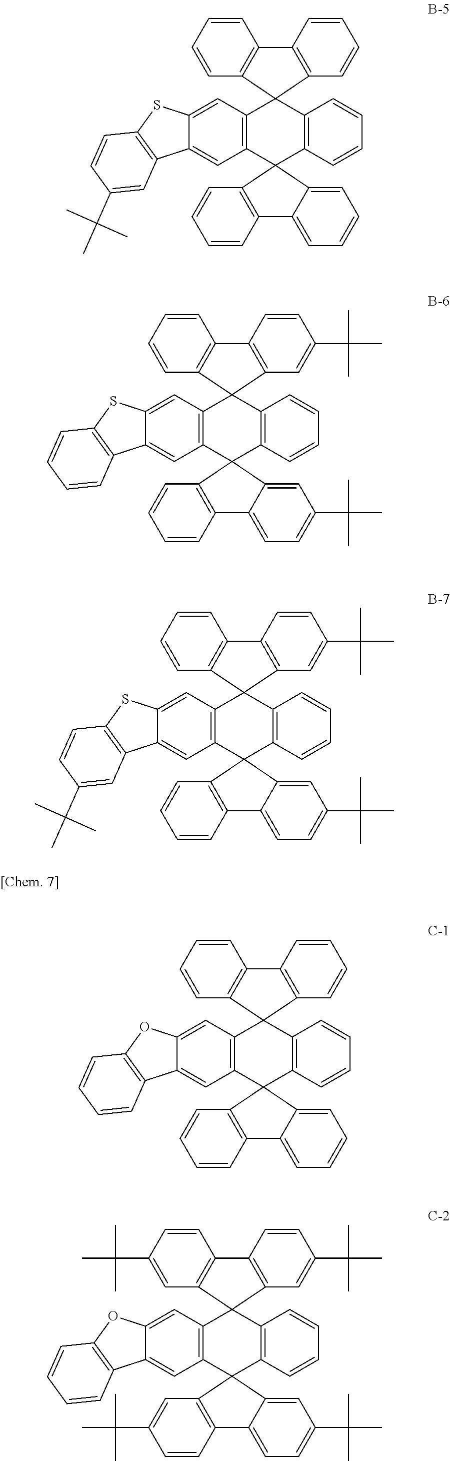

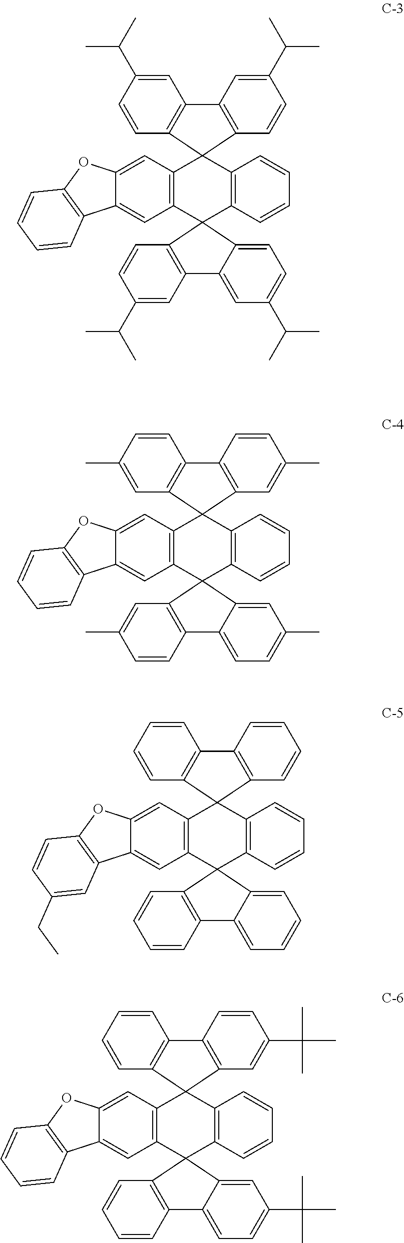 [SMILES: CC(C)c1ccc2c(c1)-c1cc(C(C)C)ccc1C21c2ccccc2C2(c3ccc(C(C)C)cc3-c3cc(C(C)C)ccc32)c2cc3c(cc21)oc1ccccc13 ; Cc1ccc2c(c1)C1(c3cc(C)ccc3-2)c2ccccc2C2(c3cc(C)ccc3-c3ccc(C)cc32)c2cc3c(cc21)oc1ccccc13 ; CCc1ccc2oc3cc4c(cc3c2c1)C1(c2ccccc2-c2ccccc21)c1ccccc1C41c2ccccc2-c2ccccc21 ; CC(C)(C)c1ccc2c(c1)C1(c3ccccc3-2)c2ccccc2C2(c3ccccc3-c3ccc(C(C)(C)C)cc32)c2cc3c(cc21)oc1ccccc13]

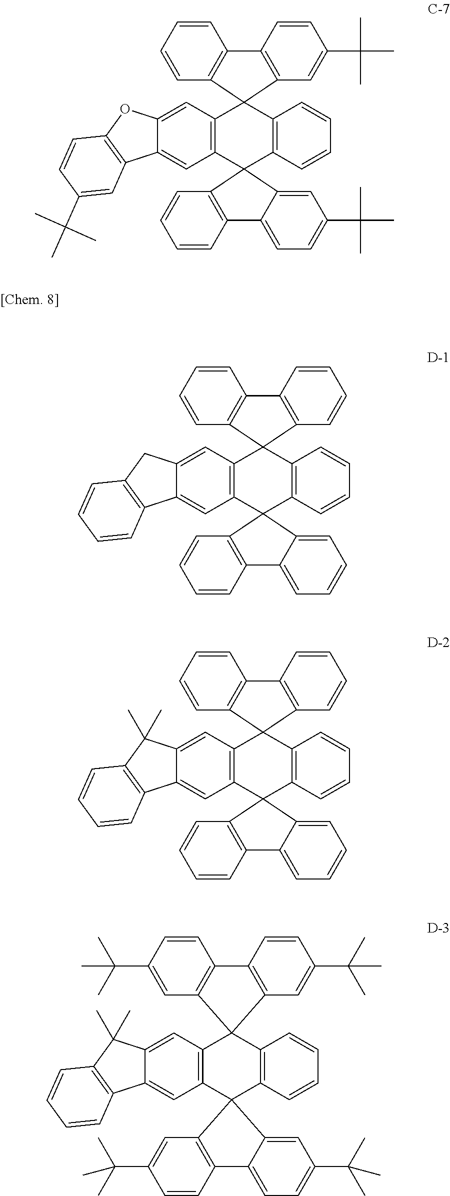

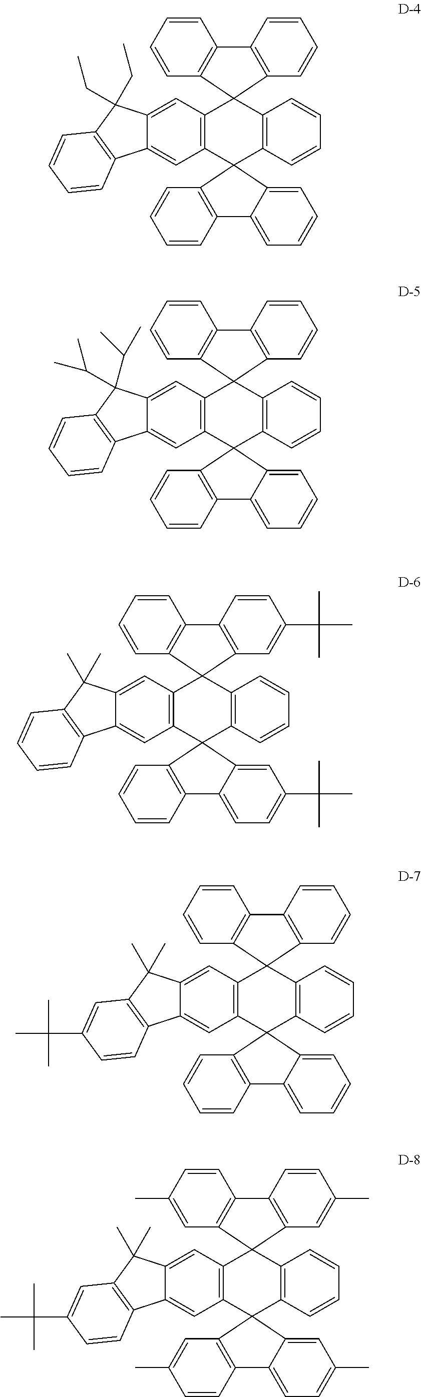

### Properties of Exemplified Compounds

### 1) Regarding Group B

The Spiro compounds shown in Group B are those where X in Formula [1] is a sulfur atom. Among them, the compounds having alkyl groups as substituents have further lower ionization potentials compared to the unsubstituted spiro compound. The T1 of every exemplified spiro compound is equivalent to that of unsubstituted spiro compound B-1.

### 2) Regarding Group C

The spiro compounds shown in Group C are those where X in Formula [1] is an oxygen atom and are further chemically stable compared to the compounds of which X is a sulfur atom. Among them, the compounds having alkyl groups as substituents have further lower ionization potentials compared to the unsubstituted spiro compound. The T1 of every exemplified spiro compound is equivalent to that of unsubstituted spiro compound C-1.

### 3) Regarding Group D

The spiro compounds shown in Group D are those where X in Formula [1] is a carbon atom and have lower polarity compared to the compounds of which X is a sulfur atom or an oxygen atom. Among them, the compounds having alkyl groups as substituents have further lower ionization potentials compared to the unsubstituted compound. The T1 of every exemplified spiro compound is equivalent to that of unsubstituted spiro compound D-1.

The structures shown as Groups B, C, and D are specific examples of the compounds. Positions of R₁ to R₅ in Formula [1] will be more specifically described by the following formula:

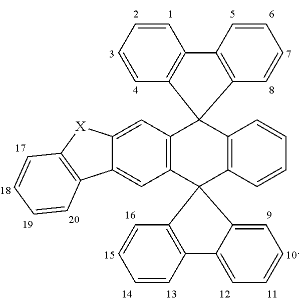

The binding position of R₁ is any of 1 to 4 of the above-mentioned formula. Similarly, the binding position of R₂ is any of 5 to 8, the binding position of R₃ is any of 9 to 12, and the binding position of R₄ is any of 13 to 16.

In the case where the substituents are alkyl groups, the ionization potential can be reduced regardless of the positions of R₁ to R₄. For example, the binding position of R₁ can be 1 or 2, the binding position of R₂ can be 6 or 7, the binding position of R₃ can be 10 or 11, and the binding position of R₄ can be 14 or 15.

The binding position of R₅ is any of 17 to 20 of the above-mentioned formula. In the case where the substituent is an alkyl group, the ionization potential can be reduced regardless of the position of R₅. For example, the binding position of R₅ can be 18 or 19.

### Description of Organic Light-Emitting Device

An organic light-emitting device according to this embodiment will be described.

The organic light-emitting device according to this embodiment includes a pair of electrodes, an anode and a cathode, and an organic compound layer disposed therebetween. The organic compound layer is a device having a spiro compound represented by Formula [1].

Examples of the organic light-emitting device produced using the spiro compound according to aspects of the present invention include those having a configuration composed of an anode, a light-emitting layer, and a cathode disposed in this order on a substrate. In this organic light-emitting device, energy is generated by recombination of electrons and/or holes supplied through the electrodes. Other examples of the organic light-emitting device include those having a configuration where an anode, a hole-transporting layer, an electron-transporting layer, and a cathode are disposed in this order; those having a configuration where an anode, a hole-transporting layer, a light-emitting layer, an electron-transporting layer, and a cathode are disposed in this order; those having a configuration where an anode, a hole-injecting layer, a hole-transporting layer, a light-emitting layer, an electron-transporting layer, and a cathode are disposed in this order; and those having a configuration where an anode, a hole-transporting layer, a light-emitting layer, a hole/exciton-blocking layer, an electron-transporting layer, and a cathode are disposed in this order. These five types of multi-layer examples merely show quite basic device configurations, and the organic light-emitting device using the spiro compound according to aspects of the present invention is not limited thereto.

The spiro compound represented by Formula [1] according to aspects of the present invention can be used as a host material or a guest material of a light-emitting layer, in particular, can be used as a host material of a light-emitting layer.

In particular, the luminous efficiency of an organic light-emitting device is high when a light-emitting layer uses a phosphorescence emitting material that emits light having a peak of an emission spectrum waveform in the range of 435 to 500 nm, i.e., emits light in a blue region as the guest material and uses a spiro compound of the present invention as the host material. This is probably because that the organic light-emitting device having a light-emitting layer of such a configuration is low in loss of triplet energy.

In the case of using the spiro compound of the present invention as the host material, the concentration of the guest material to the host material can be 0.1% by mass or more and 30% by mass or less, such as 0.5 wt % or more and 10 wt % or less.

The organic light-emitting device according to this embodiment can contain, in addition to the spiro compound according to the present invention, for example, a hole-injecting material, a hole-transporting material, a host material, a guest material, an electron-injecting material, and an electron-transporting material. These materials may be a low-molecular system or a high-molecular system.

Examples of these materials will be described below.

The hole-injecting material or the hole-transporting material can be a material possessing a high hole mobility. Examples of low-molecular or high-molecular material having hole-injecting ability or hole-transporting ability include, but not limited to, triarylamine derivatives, phenylenediamine derivatives, stilbene derivatives, phthalocyanine derivatives, porphyrin derivatives, poly(vinylcarbazole), poly(thiophene), and other electrically conductive polymers.

Examples of the host material include, but not limited to, triarylamine derivatives, phenylene derivatives, condensed ring aromatic compounds (e.g., naphthalene derivatives, phenanthrene derivatives, fluorene derivatives, and chrysene derivatives), organic metal complexes (e.g., organic aluminum complexes such as tris(8-quinolinolato)aluminum, organic beryllium complexes, organic iridium complexes, and organic platinum complexes), and polymer derivatives such as poly(phenylenevinylene) derivatives, poly(fluorene) derivatives, poly(phenylene) derivatives, poly(thienylenevinylene) derivatives, and poly(acetylene) derivatives.

Examples of the guest material include phosphorescent Ir complexes and platinum complexes shown below.

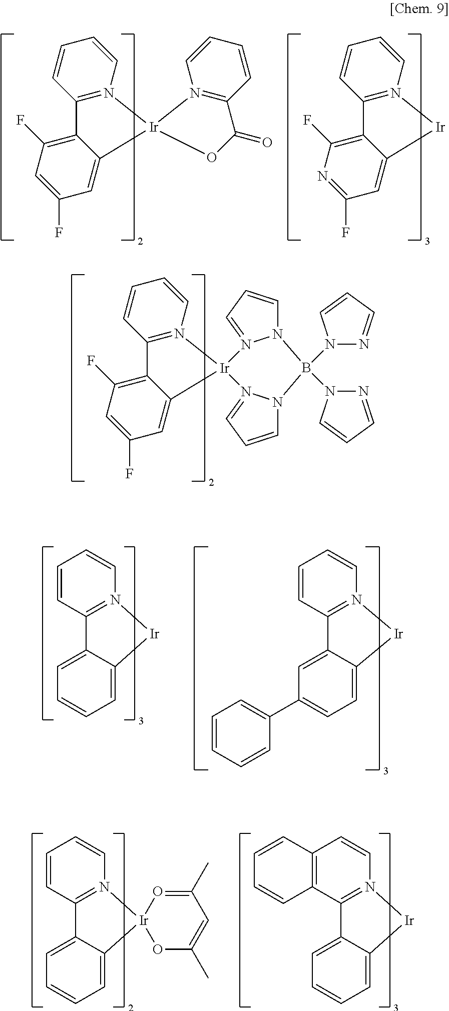

As the guest material, a fluorescent dopant also can be used. Examples of the fluorescent dopant include condensed ring compounds (e.g., fluorene derivatives, naphthalene derivatives, pyrene derivatives, perylene derivatives, tetracene derivatives, anthracene derivatives, and rubrene), quinacridone derivatives, coumarin derivatives, stilbene derivatives, organic aluminum complexes such as tris(8-quinolinolato)aluminum, organic beryllium complexes, and polymer derivatives such as poly(phenylenevinylene) derivatives, poly(fluorene) derivatives, and poly(phenylene) derivatives.

The electron-injecting material or the electron-transporting material are selected with consideration for, for example, the balance with the hole mobility of the hole-injecting material or the hole-transporting material. Examples of the material possessing the electron-injecting ability or the electron-transporting ability include, but not limited to, oxadiazole derivatives, oxazole derivatives, pyrazine derivatives, triazole derivatives, triazine derivatives, quinoline derivatives, quinoxaline derivatives, phenanthroline derivatives, and organic aluminum complexes.

The material of the anode has a high work function. Examples of such a material include simple metals such as gold, platinum, silver, copper, nickel, palladium, cobalt, selenium, vanadium, and tungsten; alloys of these simple metals; and metal oxides such as tin oxide, zinc oxide, indium oxide, indium tin oxide (ITO), and indium zinc oxide. Electrically conductive polymers such as polyaniline, polypyrrole, and polythiophene also can be used. These electrode materials may be used alone or in combination of two or more thereof. The anode may have either a monolayer structure or a multilayer structure.

The material of the cathode has a low work function. Examples of such materials include alkali metals such as lithium; alkaline earth metals such as calcium; simple metals such as aluminum, titanium, manganese, silver, lead, and chromium; alloys of these simple metals such as magnesium-silver, aluminum-lithium, and aluminum-magnesium; and metal oxides such as indium tin oxide (ITO). These electrode materials can be used alone or in combination of two or more thereof. The cathode may have either a monolayer structure or a multilayer structure.

In the organic light-emitting device according to this embodiment, a layer containing the organic compound according to this embodiment and a layer of another organic compound are layers generally formed by vacuum deposition, ionic vapor deposition, sputtering, plasma CVD, or a known method of applying the compound dissolved in a suitable solvent (e.g., spin coating, dipping, casting, an LB method, or an ink jet method). In particular, in the layer formed by vacuum deposition or application of a solution, for example, crystallization hardly occurs to achieve high long-term stability. In the case of forming a layer by application of a solution, the solution may additionally contain a suitable binder resin.

Examples of the binder resin include, but not limited to, polyvinylcarbazole resins, polycarbonate resins, polyester resins, ABS resins, acrylic resins, polyimide resins, phenol resins, epoxy resins, silicone resins, and urea resins. These binder resins may be singly used as a homopolymer or a copolymer or as a mixture of two or more of polymers. The solution for forming a layer may further contain an additive such as a known plasticizer, antioxidant, or ultraviolet absorber.

The base material having the organic light-emitting device may be an insulating member such as glass or a polyethylene terephthalate sheet (PET sheet). The PET sheet is an example of flexible members. The base material may be a doped or undoped semiconductor member. The semiconductor base material is, for example, a silicon substrate. The insulating member and the semiconductor base material may be transparent, translucent, or opaque to visible light.

### Use of Organic Light-Emitting Device

The organic light-emitting device according to aspects of the present invention can be applied not only to a display or a lighting system, but also to an exposing light source of an electrographic image-forming apparatus or a backlight of a liquid crystal display. The base material of the lighting system includes the organic light-emitting device and a converter for providing a DC voltage from an AC power source.

The display includes the organic light-emitting device according to this embodiment in a display section. This display section includes a plurality of pixels on a base material. The pixel includes an organic light-emitting device according to this embodiment and a switching device for controlling luminance. The switching device may be that for switching on and off of light emission. An example of the switching device is a transistor device, e.g., a TFT device. The anode or the cathode of the organic light-emitting device is connected to the drain electrode or the source electrode of the TFT device. The display can be used as an image-displaying apparatus of, for example, a personal computer.

The display may be an image input apparatus that includes an image input section for inputting information from, for example, an area CCD, a linear CCD, or a memory card and outputs the input image to the display section. The image input apparatus may be a portable terminal such as a mobile phone, a smartphone, or a tablet-type PC. The display may be an image pickup apparatus such as a digital camera or may be used as the display section of an ink-jet printer. Specifically, the display may have both an image output function for displaying an image based on image information input from the outside and an input function for inputting information processed into an image as an operation panel. The display may be used in the display section of a multi-functional printer.

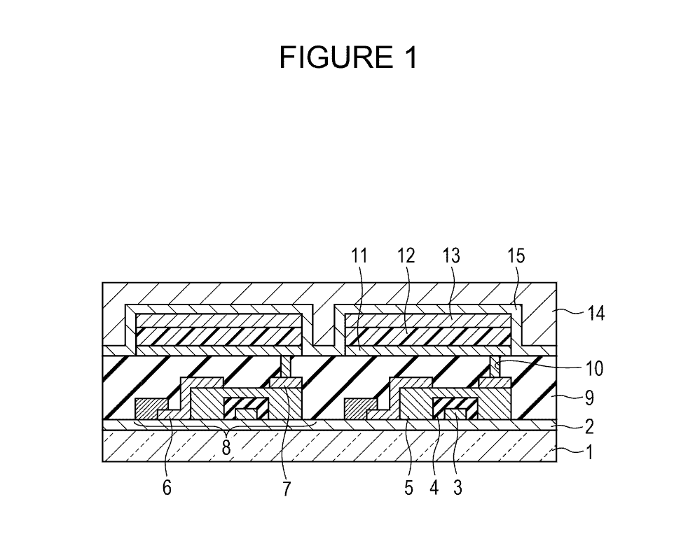

A display using the organic light-emitting device according to this embodiment will be described with reference to FIG. 1.

FIG. 1 is a schematic cross-sectional view illustrating organic light-emitting devices according to this embodiment and TFT devices as an example of the switching devices connected to the organic light-emitting devices. This FIGURE shows two pairs of the organic light-emitting device and the TFT device. The details of the structure will be described below.

The display shown in FIG. 1 includes a substrate 1 such as a glass substrate and a moisture-proof film 2 disposed on the substrate 1 for protecting the TFT devices or the organic compound layer. Reference numeral 3 denotes a metal gate electrode, reference numeral 4 denotes a gate insulating film, and reference numeral 5 denotes a semiconductor layer.

The TFT device 8 includes a semiconductor layer 5, a drain electrode 6, and a source electrode 7. An insulating film 9 is disposed on the TFT device 8. The anode 11 of the organic light-emitting device and the source electrode 7 are connected via a contact hole 10. The display is not limited to this configuration as long as either the anode or the cathode is connected to either the source electrode or the drain electrode of the TFT device.

In this drawing, the organic compound layer 12 that is a multilayer is shown as one layer. Furthermore, a first protective layer 14 and a second protective layer 15 are disposed on the cathode 13 in order to inhibit deterioration of the organic light-emitting device.

The switching device of the display according to this embodiment is not particularly limited and may be a transistor or an MIM device.

The transistor may be, for example, a thin-film transistor device having single crystal, polycrystal, or amorphous silicon.

The thin-film transistor is disposed on an insulating surface and is also called a TFT device.

The transistor may be disposed in the vicinity of the surface of a silicon crystal substrate or may be disposed on an epitaxial layer grown on a silicon crystal substrate.

### EXAMPLES

The present invention will be described in detail by the following examples, but is not limited thereto.

### Example 1

### Synthesis of Example Compound B-1

Example Compound B-1 was synthesized by a synthesis scheme shown below:

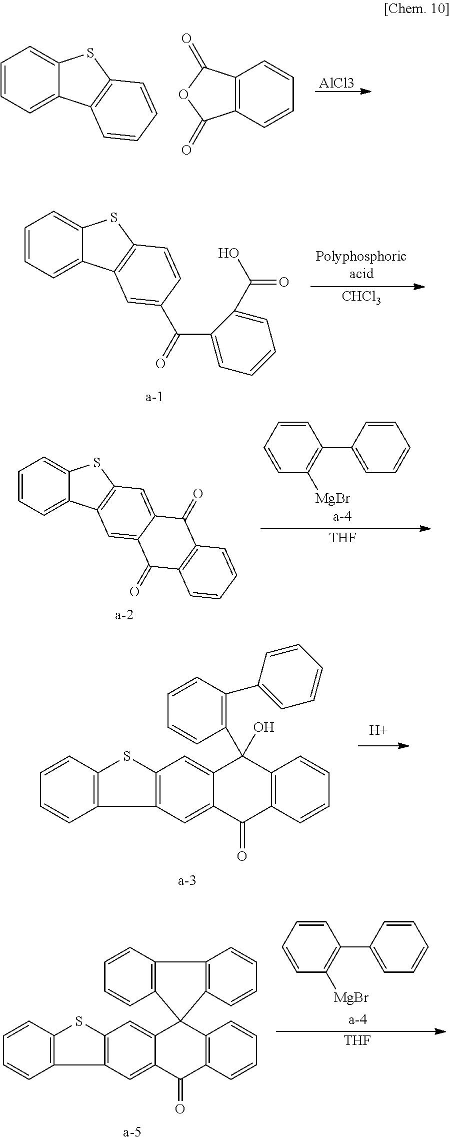

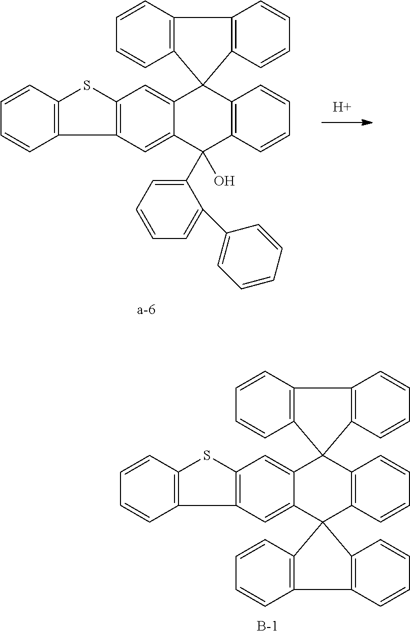

### Synthesis of Compound a-1

In a 300-mL three-neck flask, 3.0 g (16.3 mmol) of dibenzothiophene, 2.24 g (15.1 mmol) of phthalic anhydride, and 100 mL of methylene chloride were placed, and 6 g of aluminum chloride was added thereto with stirring and cooling with ice. The temperature of the mixture was raised to room temperature, followed by stirring for 3 hr. After the reaction, the organic layer was poured into 200 mL of ice water, and 10 mL of concentrated hydrochloric acid was added thereto. The mixture was stirred for 1 hr and then extracted with chloroform. The chloroform layer was dried over anhydrous sodium sulfate and concentrated, and 50 mL of heptane was added thereto. The precipitated crystals were collected by filtration to yield 4.5 g (yield: 83%) of a grayish white solid.

### Synthesis of Compound a-2

In a 100-mL three-neck flask, 4.5 g (13.5 mmol) of compound a-1, 20 mL of polyphosphoric acid, and 20 mL of chloroform were placed under a nitrogen atmosphere, and 6 g of compound a-4 was added thereto with stirring and cooling with ice. The temperature of the mixture was raised to 80° C., followed by stirring for 5 hr. After the reaction, the organic layer was poured into 200 mL of ice water, and the mixture was extracted with chloroform. The chloroform layer was dried over anhydrous sodium sulfate, followed by purification with a silica gel column (eluent: mixture of chloroform and heptane) to yield 2.3 g (yield: 54%) of compound a-2 (yellow solid).

### Synthesis of Compound a-3

In a 100-mL three-neck flask, 2.2 g (7.0 mmol) of compound a-2 and 50 mL of THF were placed under a nitrogen atmosphere, and 56 mL of a solution of 0.5 M compound a-4 in THF was added thereto with stirring and cooling with ice. The temperature of the mixture was raised to room temperature, followed by stirring for 5 hr. After the reaction, the organic layer was poured into 100 mL of ice water, and the mixture was extracted with chloroform. The chloroform layer was dried over anhydrous sodium sulfate, followed by purification with a silica gel column (eluent: mixture of chloroform and heptane) to yield 1.5 g (yield: 46%) of compound a-3 (yellow solid).

### Synthesis of Compound a-5

In a 50-mL three-neck flask, 1.5 g (3.2 mmol) of compound a-3 and 20 mL of acetic acid were placed under a nitrogen atmosphere, and 3 mL of concentrated hydrochloric acid was added thereto with stirring at room temperature. The temperature of the mixture was raised to 100° C., followed by stirring for 5 hr. After the reaction, the organic layer was poured into 100 mL of ice water, and the mixture was extracted with toluene. The toluene layer was dried over anhydrous sodium sulfate, followed by purification with a silica gel column (eluent: mixture of chloroform and heptane) to yield 1.3 g (yield: 90%) of compound a-5 (yellow solid).

### Synthesis of Compound a-6

In a 100-mL three-neck flask, 1.2 g (2.7 mmol) of compound a-5 and 50 mL of THF were placed under a nitrogen atmosphere, and 21 mL of a solution of 0.5 M compound a-4 in THF was added thereto under a nitrogen atmosphere with stirring and cooling with ice. The temperature of the mixture was raised to room temperature, followed by stirring for 5 hr. After the reaction, the organic layer was poured into 100 mL of ice water, and the mixture was extracted with chloroform. The chloroform layer was dried over anhydrous sodium sulfate, followed by purification with a silica gel column (eluent: mixture of chloroform and heptane) to yield 950 mg (yield: 58%) of compound a-6 (yellow solid).

### Synthesis of Example Compound B-1

In a 50-mL three-neck flask, 950 mg (1.57 mmol) of compound a-6 and 10 mL of acetic acid were placed under a nitrogen atmosphere, and 2 mL of concentrated hydrochloric acid was added thereto with stirring at room temperature. The temperature of the mixture was raised to 100° C., followed by stirring for 5 hr. After the reaction, the organic layer was poured into 100 mL of ice water, and the mixture was extracted with toluene. The toluene layer was dried over anhydrous sodium sulfate, followed by purification with a silica gel column (eluent: mixture of chloroform and heptane) to yield 730 mg (yield: 79%) of Example Compound B-1 (white solid).

By mass spectrometry, M+ of Example Compound B-1, 586, was confirmed.

The structure of Example Compound B-1 was confirmed by ¹H NMR measurement.

¹H NMR (CDCl₃, 400 MHz) σ (ppm): 7.98-7.94 (m, 4H), 7.61 (d, 1H), 7.57 (d, 1H), 7.46-7.42 (m, 4H), 7.31-7.15 (m, 11H), 6.88 (s, 1H), 6.80-6.77 (m, 2H), 6.43-6.40 (m, 2H).

T1 of Example Compound B-1 in a dilute toluene solution was measured.

The measured value of T1 of Example Compound B-1 was 434 nm.

T1 was determined as the first emission peak by cooling a toluene solution (1×10⁻⁴ mol/L) to 77K and measuring the phosphorescence emission spectrum at an excitation wavelength of 350 nm. The measurement was performed with a spectrometer U-3010 manufactured by Hitachi, Ltd.

### Example 2

### Synthesis of Example Compound C-1

Example Compound C-1 was synthesized as in Example 1 except that dibenzofuran was used instead of dibenzothiophene.

By mass spectrometry, M+ of Example Compound C-1, 570, was confirmed.

### Example 3

### Synthesis of Example Compound D-2

Example Compound D-2 was synthesized as in Example 1 except that 9,9-dimethyl-9H-fluorene was used instead of dibenzothiophene.

By mass spectrometry, M+ of Example Compound D-2, 596, was confirmed.

### Example 4

In this example, an organic light-emitting device having a configuration composed of anode/hole-injecting layer/hole-transporting layer/light-emitting layer/hole-exciton-blocking layer/electron-transporting layer/cathode disposed in this order on a substrate was produced by the following method.

A film of ITO was formed on a glass substrate by sputtering as an anode having a thickness of 120 nm, and the resulting product was used as a transparent electrically conductive support substrate (ITO substrate). On this ITO substrate, an organic compound layers and electrode layers shown below were successively formed by resistance heating vacuum vapor deposition in a vacuum chamber of 10⁻⁵ Pa. On this occasion, the area of electrodes facing each other was adjusted to be 3 mm². The layers were:

hole-injecting layer (40 nm): compound b-1
hole-transporting layer (10 nm): compound b-2,
light-emitting layer (30 nm): host: Example Compound B-1,
guest: compound b-3 (weight ratio: 10%),
hole-exciton-blocking layer (10 nm): compound b-4,
electron-transporting layer (30 nm): compound b-5,
metal electrode layer 1 (1 nm): LiF, and
metal electrode layer 2 (100 nm): Al.

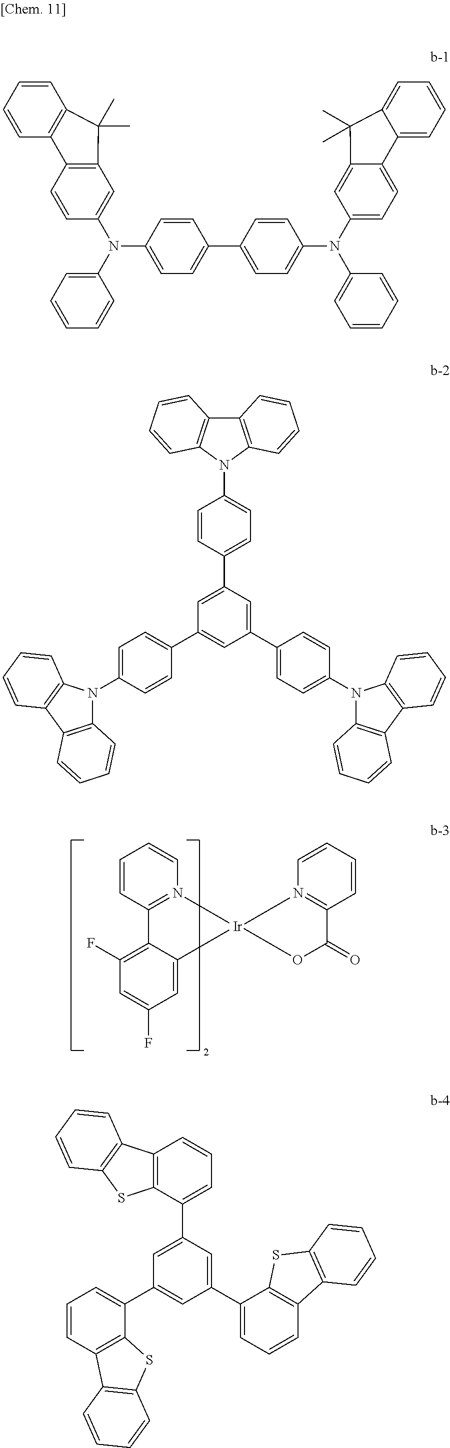

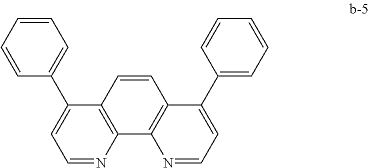 [SMILES: c1ccc(-c2ccnc3c2ccc2c(-c4ccccc4)ccnc23)cc1]

A voltage of 5.2 V was applied to the resulting organic light-emitting device using the ITO electrode as a positive electrode and the Al electrode as the negative electrode to observe blue light emission with a luminance of 2005 cd/m², a current density of 3.7 mA/cm², a luminous efficiency of 27.5 cd/A, and CIE chromaticity coordinates (0.21, 0.48).

### Example 5

An organic light-emitting device was produced as in Example 4 except that Example Compound C-1 was used as the host material of the light-emitting layer instead of Example Compound B-1.

A voltage of 5.2 V was applied to the resulting organic light-emitting device using the ITO electrode as a positive electrode and the Al electrode as the negative electrode to observe blue light emission with a luminance of 2012 cd/m², a current density of 3.6 mA/cm², a luminous efficiency of 26.6 cd/A, and CIE chromaticity coordinates (0.21, 0.46).

### Example 6

### Synthesis of Example Compound D-7

Example Compound D-7 was synthesized as in Example 1 except that 2-tert-butyl-9,9-dimethyl-9H-fluorene was used instead of dibenzothiophene.

By mass spectrometry, M+ of Example Compound D-7, 652, was confirmed.

As described by the embodiment and examples above, the present invention can provide a novel spiro compound that has a high lowest excited triplet level (T1) and can form a stable amorphous film having high chemical stability and low crystallinity. An organic light-emitting device having a high luminous efficiency and a low driving voltage can be provided by using a novel spiro compound of the present invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-090412 filed Apr. 14, 2011 and No. 2012-014365 filed Jan. 26, 2012, which are hereby incorporated by reference herein in their entirety.

1. A spiro compound represented by the following Formula [1]: 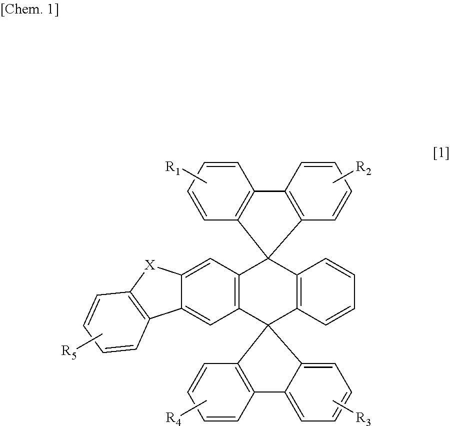
wherein, R₁ to R₅ are each independently selected from hydrogen atoms and alkyl groups having 1 to 4 carbon atoms and may be the same or different; and X is any of a sulfur atom, an oxygen atom, and a carbon atom, and when X is a carbon atom, the carbon atom may have one or two alkyl groups having 1 to 4 carbon atoms, and when the carbon atom has two alkyl groups having 1 to 4 carbon atoms, the two alkyl groups may be the same or different.

2. The spiro compound according to claim 1, wherein X in Formula [1] is a sulfur atom or an oxygen atom.

3. An organic light-emitting device comprising a pair of electrodes and an organic compound layer disposed between the pair of electrodes, wherein the organic compound layer includes a spiro compound according to claim 1.

4. The organic light-emitting device according to claim 3, wherein the organic compound layer includes a host material and a guest material, wherein the host material is the spiro compound.

5. The organic light-emitting device according to claim 4, wherein the guest material is a compound that emits phosphorescence.

6. A display comprising a plurality of pixels, wherein the pixels each include an organic light-emitting device according to claim 4 and a switching device connected to the organic light-emitting device.

7. An image input apparatus comprising a display section for displaying an image and an input section for inputting image information into the display section, wherein the display section includes a plurality of pixels each having an organic light-emitting device according to claim 3 and a switching device connected to the organic light-emitting device.

8. A lighting system comprising an organic light-emitting device according to claim 3 and a converter.
